(19) United States
(12) Patent Application Publication
(10) Pub. No.: US 2025/0029782 A1
(43) Pub. Date: Jan. 23, 2025

(54) CAPACITOR

(71) Applicant: Silergy Semiconductor Technology (Hangzhou) LTD, Hangzhou (CN)

(72) Inventors: Gang Yao, Hangzhou (CN); Huafeng Yuan, Hangzhou (CN); Fangqin Yu, Hangzhou (CN)

(21) Appl. No.: 18/760,314

(22) Filed: Jul. 1, 2024

(30) Foreign Application Priority Data
Jul. 19, 2023 (CN) 202310896316.2

(51) Int. Cl. H01G 4/01; H01G 4/30

(52) U.S. Cl. CPC H01G 4/01; H01G 4/30

(57) ABSTRACT

A capacitor can include a bottom conductive structure; at least one middle conductive structure, each middle conductive structure having a first conductive pattern and a second conductive pattern surrounding an outer side of the first conductive pattern, where the first conductive pattern and the second conductive pattern of each layer of the middle conductive structure form an interdigitated structure; and a top conductive structure having a third conductive pattern and a fourth conductive pattern arranged at an outer side of the third conductive pattern, where the third conductive pattern and the fourth conductive pattern form an interdigitated structure.

### RELATED APPLICATIONS

This application claims the benefit of Chinese Patent Application No. 202310896316.2, filed on Jul. 19, 2023, which is incorporated herein by reference in its entirety.

### FIELD OF THE INVENTION

The present invention generally relates to the field of semiconductor technology, and more particularly capacitors.

### BACKGROUND

In the semiconductor industry, capacitors are important and fundamental components. The two commonly used capacitor structures are metal-insulator-metal (MIM) capacitors and metal-oxide-metal (MOM) capacitors. Typically, MIM capacitors include insulators added between two layers of metal, while MOM capacitors are composed of a large number of parallel “fingers” or electrodes that are formed in many metal layers.

### BRIEF DESCRIPTION OF THE DRAWINGS

FIG. 1 is a decomposed structure diagram of a first example capacitor, in accordance with embodiments of the present invention.

FIG. 2 is a top view of the bottom conductive structure of a first example capacitor, in accordance with embodiments of the present invention.

FIG. 3 is a top view of the second middle conductive structure of the first example capacitor, in accordance with embodiments of the present invention.

FIG. 4 is a top view of the first middle conductive structure of the first example capacitor, in accordance with embodiments of the present invention.

FIG. 5 is a top view of the top conductive structure of the first example capacitor, in accordance with embodiments of the present invention.

FIG. 6 is a decomposed structure diagram of a second example capacitor, in accordance with embodiments of the present invention.

FIG. 7 is a decomposed structure diagram of a third example capacitor, in accordance with embodiments of the present invention.

FIG. 8 is a decomposed structure diagram of a fourth example capacitor, in accordance with embodiments of the present invention.

FIG. 9 is a decomposed structure diagram of a fifth example capacitor, in accordance with embodiments of the present invention.

FIG. 10 is a decomposed structure diagram of a sixth example capacitor. in accordance with embodiments of the present invention.

FIG. 11 is a decomposed structure diagram of a seventh example capacitor. in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

For the design of high-accuracy analog-to-digital converters (ADCs), the accuracy and matching of capacitors are crucial, and the capacitors in most designs are specially processed to meet such design accuracy requirements. In many designs, metal-insulator-metal (MIM) capacitors with higher accuracy and larger areas are used to meet such precision requirements. Due to the limited minimum size of MIM capacitors, the area of the capacitor matrix is relatively large, and the mismatch can also be severe. Additionally, an additional mask layer is used, which results in relatively high costs. Some designs also utilize metal-oxide-metal (MOM) capacitors with standard interdigital structures, but the parasitic effects of this type of structure may have a significant impact on the circuit accuracy.

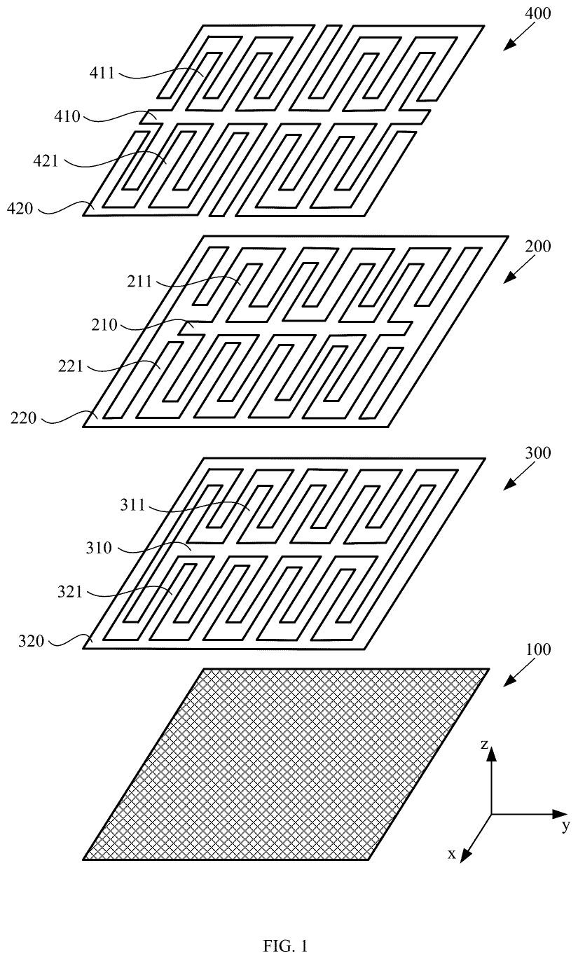

Referring now to FIG. 1, shown is a decomposed structure diagram of a first example capacitor, in accordance with embodiments of the present invention. The example capacitor can include bottom layer conductive structure 100, at least two middle conductive structures 200, 300, and top layer conductive structure 400, which can be sequentially stacked. Middle conductive structures 200, 300, and top conductive structure 400 may each include two conductive patterns staggered to form an interdigitated structure. One of the two conductive patterns can connect to a first capacitive pole, and the other of the two conductive patterns can connect to a second capacitive pole, such that the two conductive patterns of the same conductive structure form a sidewall capacitor. The conductive patterns connected to different capacitive poles in adjacent conductive structures may partially overlap with each other in the stacking direction (z-axis direction in the figure) to form a plate capacitor. Each layer of the conductive structure can be made of the same or different conductive materials (e.g., same metal material).

For example, the sidewall capacitor may refer to a capacitor formed by two conductive patterns connected to different capacitive poles in the same conductive structure. The plate capacitor may refer to a capacitor formed by two conductive patterns connected to different capacitor poles in adjacent conductive structures. The first capacitive pole can be an upper plate of the capacitor, and the second capacitive pole can be a lower plate of the capacitor. Further, in the same conductive structure (middle conductive structure 200, 300 or top conductive structure 400), the conductive pattern arranged at the inner side can connect to the first capacitive pole, and the conductive pattern arranged at the outer side can connect to the second capacitive pole. Bottom conductive structure 100 can connect to the second capacitive pole. That is, in the semiconductor device, the conductive pattern arranged at the outer side and bottom conductive structure 100 can connect to each other as the lower plate of the capacitor, and the conductive pattern arranged at the inner side can connect to each other as the upper plate of the capacitor.

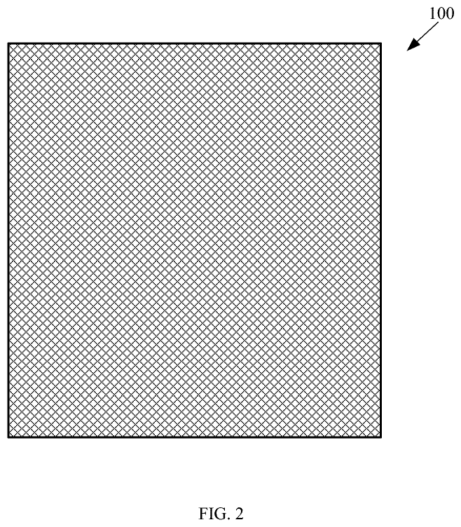

Referring now to FIG. 2, shown is a top view of the bottom conductive structure of a first example capacitor, in accordance with embodiments of the present invention. Bottom conductive structure 100 may adopt a whole rectangular structure, and bottom conductive structure 100 may be arranged at least in the second metal layer of the semiconductor device, which can effectively reduce the influence of substrate noise on capacitor. For example, the second metal layer may refer to the metal layers sequentially arranged on the substrate, and the first metal layer may be closest to the substrate. As bottom conductive structure 100 is used as the lower electrode plate of the whole capacitor, the larger area can reserve a bottom layer wiring channel for the connection of the lower electrode plate. Moreover, bottom conductive structure 100 can make the capacitor arrangement of the overall structure more compact, capacitance adhesion may be increased, the matrix area of the capacitor can be reduced, and thus the mismatch effect of the process gradients on the capacitance matrix may be reduced.

Further, the outermost dimensions of each layer of conductive structure of the capacitor may be the same, and the projection of bottom conductive structure 100 along the stacking direction can cover the projection of middle conductive structures 200, 300, and top conductive structure 400 along the stacking direction. That is, bottom conductive structure 100, at least two middle conductive structures 200, 300, and top conductive structure 400 can be sequentially stacked, and adjacent conductive structures may partially overlap in the stacking direction. The outermost dimensions of all middle conductive structures 200, 300, and top conductive structure 400 may be less than or equal to the outermost dimensions of bottom conductive structure 100. The outer edge of bottom conductive structure 100 connected to the second capacitive pole can be electrically connected to the conductive patterns arranged at the outer side of other conductive structures through a conductive via.

In particular embodiments, bottom conductive structure 100 can also be set to be higher than any layer of the second metal layer in the device layout (e.g., bottom conductive structure 100 can be a third or fourth metal layer, etc.). The higher the level of the metal layer, the smaller the parasitic capacitance of the device. In this example, the capacitor can include at least two stacked middle conductive structures, each middle conductive structures 200 and 300 can include a first conductive pattern, and the second conductive pattern surrounding the outer side of first conductive pattern, respectively. The conductive pattern connected to the first capacitive pole and conductive pattern 220 and 320 connected to the second capacitive pole may form an interdigital structure in the same middle conductive structure. As such, the sidewall capacitor can be formed by first and second conductive patterns.

The first conductive pattern can include a first comb tooth pattern, and the second conductive pattern can include a second comb tooth pattern. For example, the first and second comb tooth patterns in the same middle conductive structure can be alternately arranged to form sidewall capacitor. For example, comb tooth patterns 211 and 221 in the same middle conductive structure 200 may be alternately arranged to form sidewall capacitor, and comb tooth patterns 311 and 321 in the same middle conductive structure 300 can be alternately arranged to form side wall capacitor. The first and second comb tooth patterns of the adjacent middle conductive structures may form a plate capacitor in the first direction (the z-axis direction in the figure should be noted, including the direction indicated by the arrow on the z-axis and the direction opposite to the arrow). For example, comb tooth pattern 211 of middle conductive structure 200 and comb tooth pattern 321 of the adjacent middle conductive structure 300 may form a plate capacitor in the first direction. Comb tooth pattern 311 of middle conductive structure 300 and comb tooth pattern 221 of the adjacent middle conductive structure 200 may form a plate capacitor in the first direction.

In particular embodiments, at least two middle conductive structures can include at least one middle conductive structure 200 and at least one middle conductive structure 300 that are alternately stacked. The positions of comb tooth pattern 211 of middle conductive structure 200 and comb tooth pattern 321 of intermediate conductive structure 300 can correspond in the z-axis direction. For example, the projections of comb tooth pattern 211 of middle conductive structure 200 and comb tooth pattern 321 of intermediate conductive structure 300 may partially overlap in the z-axis direction. The positions of comb tooth pattern 221 of middle conductive structure 200 and comb tooth pattern 311 of middle conductive structure 300 can correspond in the z-axis direction. For example, the projections of comb tooth pattern 221 of middle conductive structure 200 and comb tooth pattern 311 of intermediate conductive structure 300 may partially overlap in the z-axis direction.

It should be noted that conductive pattern 210, conductive pattern 220, comb tooth pattern 211, middle strip-shaped connecting part 212, comb tooth pattern 221, edge annular connecting part 222, tooth part 213, and tooth part 223 described below may all be structures within middle conductive structure 200. Conductive pattern 310, conductive pattern 320, comb tooth pattern 311, middle strip-shaped connecting part 312, comb tooth pattern 321, edge annular connecting part 322, tooth part 313, and tooth part 323 described below may all be structures within middle conductive structure 300.

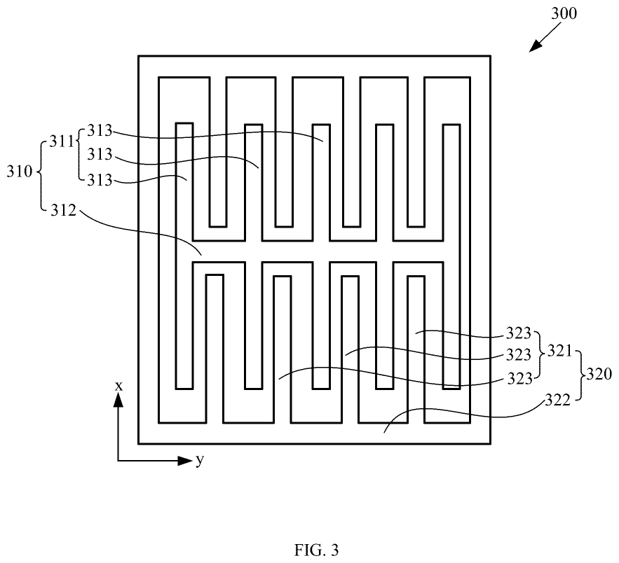

Referring now to FIG. 3, shown is a top view of the second middle conductive structure of the first example capacitor, in accordance with embodiments of the present invention. Middle conductive structure 300 can include conductive pattern 310 and conductive pattern 320. Conductive pattern 310 can include multiple tooth parts 313 extending along a third direction (x-axis direction in the figure, whereby the x-axis direction can include a direction indicated by the arrow of the x-axis in the figure and a direction opposite to the direction indicated by the arrow) and middle strip-shaped connecting portion 312 extending along a second direction (y-axis direction in the figure, whereby the y-axis direction can include a direction indicated by the arrow of the y-axis in the figure and a direction opposite to the direction indicated by the arrow).

Multiple tooth parts 313 can connect at equal intervals or at a certain interval to both sides of the long side of middle strip-shaped connecting part 312, and middle strip-shaped connecting part 312 can cooperate with multiple tooth part 313 to form comb tooth pattern 311. Multiple tooth parts 313 can extend in the direction away from middle strip-shaped connecting part 312, such that conductive pattern 310 can be a fishbone like structure with the middle strip-shaped connecting part 312 as the backbone. Conductive pattern 310 in the shape of a fishbone can be composed of middle strip-shaped connecting part 312 and two comb tooth patterns 311 that are symmetrical with middle strip-shaped connecting part 312 as the axis of symmetry. In this example, the z-axis direction, the y-axis direction, and the x-axis direction are perpendicular to each other. The size of conductive pattern 310 can be essentially the same as that of conductive pattern 210. For example, the size of conductive pattern 310 can be exactly the same as the size of conductive pattern 210.

Conductive pattern 320 can include multiple tooth parts 323 extending along the x-axis direction and edge annular connecting part 322. In this example, edge annular connecting part 322 is a hollow rectangular ring, and the four sides of the rectangle are respectively set along the y-axis direction and the x-axis direction. Multiple tooth parts 323 can connect at equal intervals or at certain intervals to side edges of edge annular connecting part 322 extending along the y-axis direction, and the side edges can cooperate with multiple tooth parts 323 to form comb tooth pattern 321. Tooth parts 323 can extend towards the direction from edge annular connecting part 322 to middle strip-shaped connecting part 312. Since tooth parts 313 can connect to the first capacitive pole and tooth parts 323 can connect to the second capacitive pole, a side wall capacitor can be formed between tooth parts 313 and tooth parts 323, which are arranged in a staggered and parallel manner.

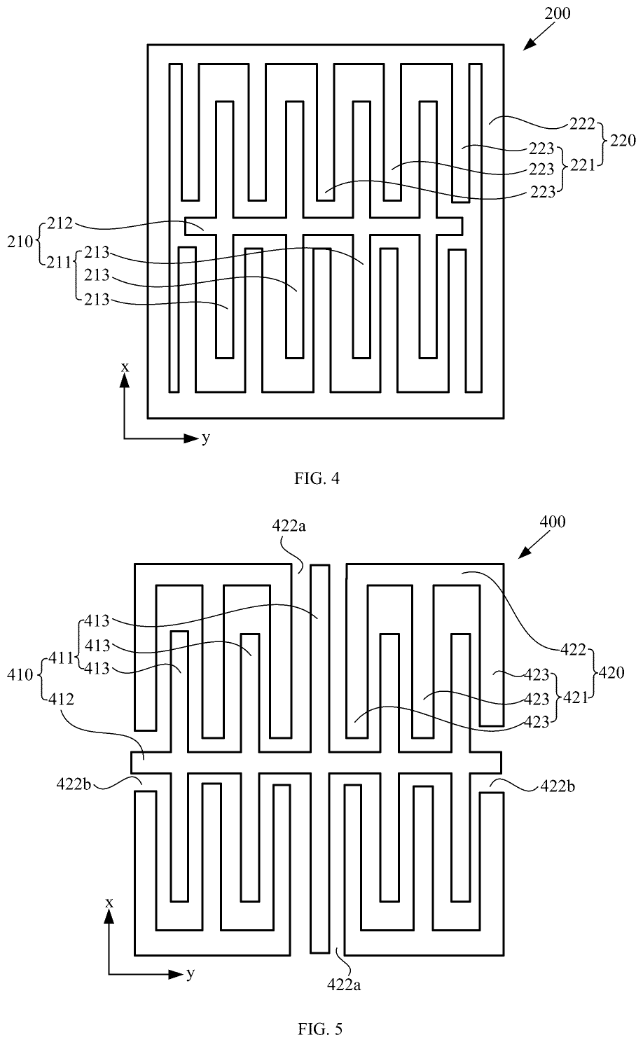

Referring now to FIG. 4, shown is a top view of the first middle conductive structure of the first example capacitor, in accordance with embodiments of the present invention. Middle conductive structure 200 can include conductive patterns 210 and 220. Conductive pattern 210 can include multiple tooth parts 213 extending along the x-axis direction and middle strip-shaped connecting part 212 extending along the y-axis direction. Multiple tooth parts 213 can connect at equal intervals or at certain intervals to both sides of the long side of middle strip-shaped connecting part 212. Middle strip-shaped connecting part 212 can cooperate with multiple tooth part 213 to form comb tooth pattern 211. Multiple tooth parts 213 can extend in the direction away from middle strip-shaped connecting part 212 to form a fishbone like structure with middle strip-shaped connecting part 212 as the backbone of conductive pattern 210. Conductive pattern 210 in the shape of a fishbone is composed of middle strip-shaped connecting part 212 and two comb tooth patterns 211 symmetrically arranged with middle strip-shaped connecting part 212 as the symmetry axis.

Conductive pattern 220 can include multiple tooth parts 223 extending along the x-axis direction and edge annular connecting part 222. In this example, edge annular connecting part 222 is a hollow rectangular ring, and the four side edges of the rectangle are respectively set along the y-axis direction and the x-axis direction. Multiple tooth parts 223 can connect at equal intervals or at certain intervals to the side edges of edge annular connecting part 222 that extend along the y-axis direction, and the side edges can cooperate with multiple tooth parts 223 to form comb tooth pattern 221. Multiple tooth parts 223 can extend towards the direction from edge annular connecting part 222 to middle strip-shaped connecting part 212. Since tooth parts 213 can connect to the first capacitive pole and tooth parts 223 can connect to the second capacitive pole, a sidewall capacitor can be formed between tooth parts 213 and tooth parts 223 which are arranged in a staggered and parallel manner.

As shown in FIG. 1, middle conductive structures 200 and 300 may have undergone misalignment treatment, and the two can be alternately arranged. In the z-axis direction, tooth parts 213 can correspond to tooth parts 323, and tooth parts 223 can correspond to tooth parts 313. That is, the projections of tooth parts 213 and 323 may partially overlap in the z-axis direction, and the projections of tooth parts 223 and 313 may partially overlap in the z-axis direction. Due to the fact that tooth parts 213 and 313 can connect to the first capacitive pole, and tooth parts 223 and 323 can connect to the second capacitive pole, a plate capacitor may be formed between the corresponding first and second tooth parts in the z-axis direction.

In particular embodiments, in middle conductive structure 200, tooth parts 213 on one side can be arranged at positions other than the quartering point and endpoint of middle strip-shaped connecting part 212, and tooth parts 213 on both sides of middle strip-shaped connecting part 212 may be symmetrical to each other. Tooth parts 223 and 213 can be arranged in a staggered manner on one side. In middle conductive structure 300, tooth parts 313 on one side may be arranged at the quarter point and endpoint of middle strip-shaped connecting part 312, and tooth parts 313 on both sides of middle strip-shaped connecting part 312 can be symmetrical to each other. Four tooth parts 323 and 313 may be arranged in a staggered manner on one side.

In particular embodiments, in middle conductive structure 200, tooth parts 213 on one side can be arranged at the quarter point and endpoint of middle strip-shaped connecting part 212, and tooth parts 213 on both sides of middle strip-shaped connecting part 212 may be symmetrical to each other. Tooth parts 223 and 213 can be arranged in a staggered manner on one side. In the middle conductive structure 300, tooth portions 313 on one side may be arranged at positions other than the quarter point and endpoint of middle strip-shaped connecting part 312, and tooth parts 313 on both sides of middle strip-shaped connecting part 312 can be symmetrical to each other. Tooth parts 323 and 313 may be arranged in a staggered manner on one side.

In particular embodiments, in middle conductive structure 200 can include ‘a’ (e.g., a is a positive integer) tooth parts 213 on one side, and tooth parts 213 on both sides of middle strip-shaped connecting part 212 may be symmetrical to each other. Also, ‘a+1’ tooth parts 223 and ‘a’ tooth parts 213 on one side may be arranged in a staggered manner. Tooth parts 213 can be equidistant and arranged on two sides of middle strip-shaped connecting part 212, with its spacing meeting the minimum design rule. Middle conductive structure 300 can include ‘b’ (e.g., b is a positive integer, whereby b+1=a or b−1=a) tooth parts 313 on one side, and tooth parts 313 on both sides of middle strip-shaped connecting part 312 can be symmetrical to each other. Also, ‘b−1’ tooth parts 323 and ‘b’ tooth parts 313 on one side may be arranged in a staggered manner. Tooth parts 313 can be equidistant and arranged on two sides of middle strip-shaped connecting part 312, with its spacing meeting the minimum design rule. Optionally, ‘a’ can be a non-zero even number and ‘b’ is an odd number.

Referring now to FIG. 5, shown is a top view of the top conductive structure of the first example capacitor, in accordance with embodiments of the present invention. Top conductive structure 400 can include conductive patterns 410 and 420 arranged on the outer side of conductive pattern 410. Conductive pattern 410 can include multiple tooth parts 413 set along the x-axis direction, and top connecting part 412 set along the y-axis direction. Multiple tooth parts 413 can connect at equal intervals or at certain intervals to both sides of the long side of top connecting part 412. Top connecting part 412 can cooperate with multiple tooth parts 413 to form comb tooth pattern 411. Multiple tooth parts 413 can extend along a direction away from top connecting part 412, and conductive pattern 410 can be a fishbone like structure with layer connecting portion 412 as the backbone. The fishbone shaped conductive pattern 410 can include top connecting part 412 and comb tooth pattern 411 symmetrically arranged with top connecting part 412 as the symmetry axis.

Conductive pattern 420 can include multiple tooth parts 423 arranged along the x-axis direction and top connecting parts 422. Top connecting part 422 may be a strip-shaped structure parallel to top connecting part 412, and top connecting part 422 can match the side edges of edge annular connecting parts 322 and 222 extending along the y-axis direction. Multiple tooth parts 423 can connect at equal intervals or at certain intervals to one side of top connecting part 422 near first top-layer connecting part 412. Top connecting part 422 can cooperate with multiple tooth parts 423 to form comb tooth pattern 421. Multiple tooth parts 423 can extend towards the direction from top connecting part 422 to top connecting part 412. Because tooth parts 413 is connected to the first capacitive pole and tooth parts 423 is connected to the second capacitive pole, a sidewall capacitor may be formed between tooth parts 413 and 423, which can be arranged in an alternating and parallel manner.

In particular embodiments, tooth parts 413 connected to top connecting part 412 may correspond to the positions of tooth parts 313 connected to middle strip-shaped connecting part 312 in the z-axis direction. The projections of tooth parts 413 and 313 may partially overlap along the z-axis direction. The length of top connecting part 412 can be greater than the length of middle strip-shaped connecting parts 212 and 312. The ends of top connecting part 412 may not be arranged with tooth parts 413, and the length of tooth part 413 located at the middle position of the tooth parts 413 can be greater than the length of the other tooth parts 413. In some examples, ‘b’ (e.g., b is a positive integer) tooth parts 413 can be set on top connecting part 412, and the positions of ‘b’ tooth parts 313 and ‘b’ tooth parts 413 can correspond in the z-axis direction. Optionally, ‘b’ can be an odd number. Each tooth part 413 may be equidistant and arranged on top connecting part 412 with a spacing that meets the minimum design rule.

In addition, multiple top connecting parts 422 can be arranged on both sides of conductive pattern 410, and each top connecting part 422 may be parallel to top connecting part 412. At least two top connecting parts 422 can be arranged on one side of the long side of top connecting part 412, and adjacent top connecting parts 422 may be located in the same straight line and spaced at first interval of 422a between them. That is, at least four top connecting parts 422 can be divided into two groups of equal quantity, and the two groups may be symmetrically arranged with top connecting part 412 as the axis symmetry. Top connecting part 422 set on the same side can be located on the same straight line and interval 422a between them. In tooth parts 413, tooth part 413 that correspond to the position of interval 422a, may extend along the x-axis direction and penetrate deep into interval 422a. In this example, the two ends of tooth part 413 located in the middle position of tooth parts 413 may extend into two interval 422a, and the ends of tooth parts 413 located at middle position can be flush with the outer edge of top-layer connecting part 422.

Tooth parts 423 can connect to top connecting part 422, and may extend towards a direction from top connecting part 422 to top connecting part 412. Tooth parts 423 on opposite sides of top-layer connecting part 412 can be symmetrically arranged with top connecting part 412 as the axis symmetry. Also, there may be a gap (e.g., interval 422b) between the two opposite tooth parts 423 to accommodate top connecting part 412. The two ends of top connecting part 412 may extend into each interval 422b. The two ends of top connecting part 412 can be flush with the outermost tooth parts 423. For example, intervals 422a and 422b can be metal connection interfaces.

Each top connecting part 422 can connect to at least two tooth parts 423, and tooth parts 423 may extend towards conductive pattern 410. In this example, each top connecting part 422 can connect to tooth parts 423, and top connecting part 422 and tooth parts 423 are perpendicular to each other and form an “E” shape. Moreover, top conductive structure 400 can include four conductive patterns 420, with four “E” shaped patterns symmetrically arranged pair wise as shown in FIG. 5. Tooth parts 423 arranged along the x-axis can be parallel to each other and may form three parallel lines of “E” shape. Top connecting part 412 extending along the y-axis may form a line perpendicular to the three parallel lines of “E” shape.

Tooth parts 423 can be spaced on one side of top connecting part 422 near conductive pattern 410, and tooth parts 423 may be staggered with the tooth parts 413 to form a sidewall capacitor. The outermost tooth parts 423 (which may form a side wall capacitance with only one tooth portion 413) can connect to the edge annular connecting part 222 through a conductive via. In this example, the length of tooth parts 423 connected to edge annular connecting part 222 may be shorter than or equal to the length of the other tooth parts 423.

In particular embodiments, middle conductive structure 200 can be adjacent to top conductive structure 400. Comb tooth pattern 411 may correspond to the adjacent comb tooth pattern 221 in the z-axis direction, while comb tooth pattern 421 may correspond to the adjacent comb tooth pattern 211 in the z-axis direction. That is, in the z-axis direction, the positions of tooth parts 423, 213, and 323 may correspond to each other, and their projections in the z-axis direction may have overlapping parts. In the z-axis direction, the positions of tooth parts 413, 223, and 313 may correspond to each other, and their projections in the z-axis direction may have overlapping parts.

In particular embodiments, all first conductive patterns 210, 310, and conductive pattern 410 can connect to the first capacitive pole and are electrically connected to each other, while bottom conductive structure 100, all conductive patterns 220, 320, and 420 can connect to the second capacitive pole and maybe electrically connected to each other. Conductive pattern 410 and the adjacent conductive pattern 220 may form a plate capacitor structure, and conductive pattern 420 and the adjacent conductive pattern 210 may form a plate capacitor structure. Also, conductive patterns 210 and 320 in the adjacent two layers may form a plate capacitor structure, and conductive patterns 310 and 220 in the adjacent two layers may form a plate capacitor structure.

The conductive patterns of adjacent layers can connect by setting interlayer conductive vias, and all first conductive patterns 210 and 310 can connect to conductive pattern 410 through conductive via(s). Ends of conductive pattern 410 in intervals 422a and 422b can connect to the first capacitive pole. All conductive patterns 210, 310, and 410 can connect to each other to form the upper plate of the overall structure. Top connecting part 422, all edge annular connecting parts 222, 322, and bottom conductive structure 100 can connect to each other to form a lower plate of the overall structure. In this example, the capacitor can also include a dielectric layer, which may be arranged between adjacent conductive structures. The dielectric layer can include insulating materials, such as silicon or silicon oxide. The material of the dielectric layer can be a low k dielectric material (low k dielectric material refers to a dielectric material with a relative dielectric constant greater than or equal to 2.6 but less than or equal to 3.9) or an ultra-low k dielectric material (ultra-low k dielectric material refers to a dielectric material with a relative dielectric constant less than 2.6), thereby parasitic capacitance in capacitors may be reduced. Among them, the material of each conductive pattern can be one or more combinations of copper, aluminum, tungsten wire, or polycrystalline silicon.

The process for forming the dielectric layer and conductive pattern can be selected as Low Pressure Chemical Vapor Deposition (LPCVD), Chemical Vapor Deposition (CVD), Low Temperature Chemical Vapor Deposition (LTCVD), Plasma Chemical Vapor Deposition (PCVD), Rapid Thermal Chemical Vapor Deposition (RTCVD), and Plasma Enhanced Chemical Vapor Deposition (Plasma). Enhanced Chemical Vapor Deposition (PECVD), etc. Among them, conductive patterns can be etched using masks after deposition, or they can be directly deposited into grooves by forming grooves with predetermined patterns. In the first example above, the capacitor may only include two middle conductive structures, which are middle conductive structures 200 and 300. For example, middle conductive structure 200 can include a conductive pattern that matches the shape of top conductive structure 400. That is, conductive patterns 210 and 410 may be staggered in the z-axis direction, and conductive patterns 220 and 420 may be staggered in the z-axis direction. The projections of conductive patterns 210 and 420 in the z-axis direction may partially overlap, and the projections of conductive patterns 220 and 410 in the z-axis direction may partially overlap.

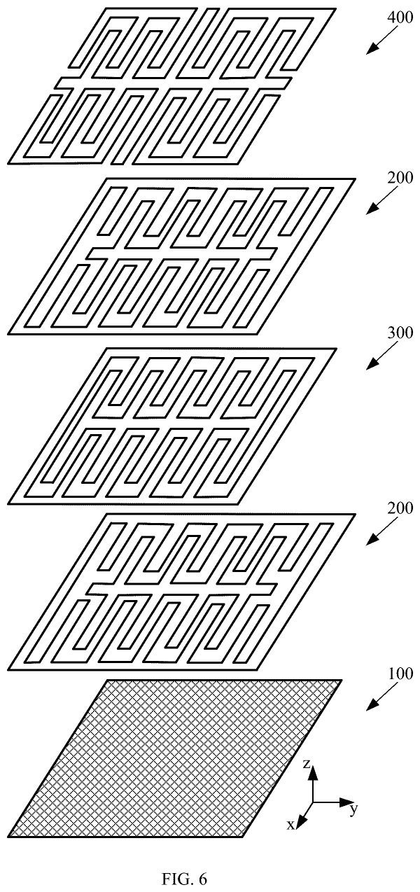

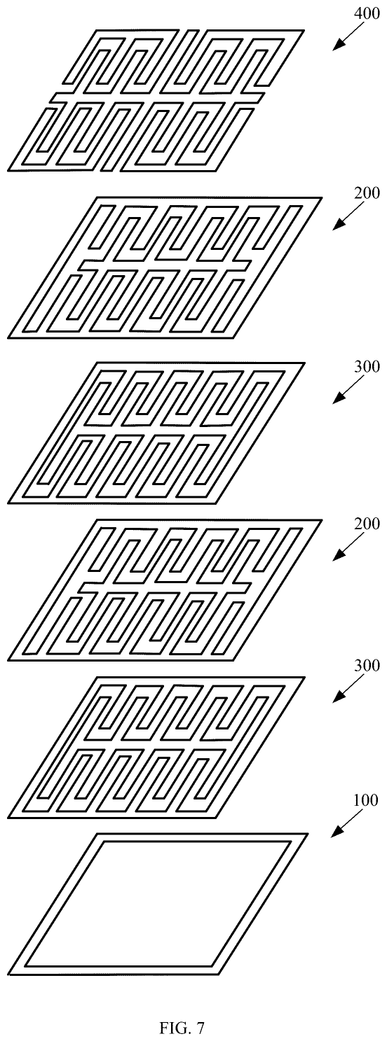

Referring now to FIG. 6, shown is a decomposed structure diagram of a second example capacitor, in accordance with embodiments of the present invention. In this particular example, the capacitor can include three middle conductive structures 200 and 300. For example, the three middle conductive structures can include two middle conductive structures 200 and one middle conductive structure 300. Middle conductive structures 200 and 300 may be alternately stacked; that is, there can be middle conductive structure 300 sandwiched between two first middle conductive structures 200. Top conductive structure 400 may be arranged on upper side of upper middle conductive structure 200, and bottom conductive structure 100 may be arranged on a lower side of lower middle conductive structure 200. For example, middle conductive structure 200 can include a conductive pattern that matches the shape of top conductive structure 400. That is, conductive patterns 210 and 410 may be staggered in the z-axis direction, and conductive patterns 220 and 420 may be staggered in the z-axis direction. The projections of conductive patterns 210 and 420 in the z-axis direction may partially overlap, and the projections of conductive patterns 220 and 410 in the z-axis direction may partially overlap.

In particular embodiments, the capacitor can include an odd number of middle conductive structures. For example, if there are 2n+1 (e.g., n is a positive integer) middle conductive structures, then the middle conductive structures may include n+1 first middle conductive structures 200 and n second middle conductive structures 300. Middle conductive structures 200 and 300 may be alternately stacked, and the top layer and bottom layer of the stacked middle conductive structures can both be middle conductive structure 200. Top conductive structure 400 and bottom conductive structure 100 can be respectively arranged on both sides of the two outermost middle conductive structures 200.

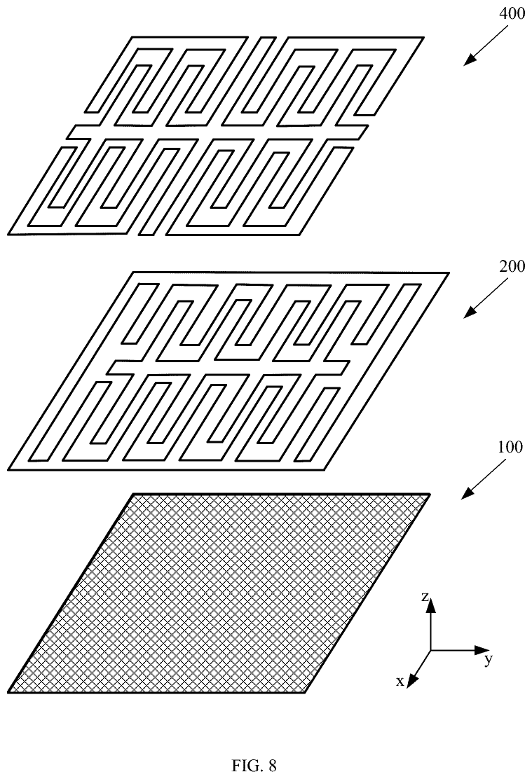

Referring now to FIG. 7, shown is a decomposed structure diagram of a third example capacitor, in accordance with embodiments of the present invention. In this particular example, the capacitor can include four middle conductive structures. For example, the four middle conductive structures can include two middle conductive structures 200 and two middle conductive structures 300. Middle conductive structures 200 and 300 may be alternately stacked to form a structure including middle conductive structure 200-middle conductive structure 300-middle conductive structure 200-middle conductive structure 300. Top conductive structure 400 can be arranged on one side of middle conductive structure 200 located in the outermost side, and bottom conductive structure 100 may be arranged on one side of middle conductive structure 300 located in the outermost side. For example, middle conductive structure 200 can include a conductive pattern that matches the shape of top conductive structure 400. That is, conductive patterns 210 and 410 may be staggered in the z-axis direction, and conductive patterns 220 and 420 may be staggered in the z-axis direction. The projections of conductive patterns 210 and 420 in the z-axis direction may partially overlap, and the projections of conductive patterns 220 and 410 in the z-axis direction may partially overlap.

In some examples, the capacitor can include an even number of intermediate conductive structures. For example, if there are 2n (e.g., n is a positive integer) middle conductive structures, then the middle conductive structures include n first middle conductive structures 200 and n second middle conductive structures 300. Middle conductive structures 200 and 300 may be alternately stacked, and top layer and bottom layer of the stacked middle conductive structures can respectively be middle conductive structure 200 and middle conductive structure 300. Top conductive structure 400 can be arranged on one side of middle conductive structure 200 in the outermost layer, and bottom conductive structure 100 may be arranged on one side of intermediate conductive structure 300 in the outermost layer.

In addition, the capacitor structure can essentially ignore the plate capacitors and may only include the sidewall capacitor in the same layer, thereby simplifying the overall structure. In deep submicron integrated circuit design, the width of the metal wire is already smaller than the thickness of the metal wire. Due to the further reduction of spacing of the metal layers, the capacitance value of the sidewall capacitor can be larger than the capacitance value of the plate capacitor. The examples below conform to this structure and are capacitors mainly composed of side wall capacitors.

Referring now to FIG. 8, shown is a decomposed structure diagram of a fourth example capacitor, in accordance with embodiments of the present invention. The capacitor can include bottom conductive structure 100, middle conductive structure 200, and top layer conductive structure 400 sequentially arranged. Conductive pattern 210 of middle conductive structure 200 and conductive pattern 410 of top conductive structure 400 can connect to the first capacitive pole and can be electrically connected to each other. Bottom conductive structure 100, conductive pattern 220 of middle conductive structure 200, and conductive pattern 420 of top conductive structure 400 can connect to the second capacitive pole and may be electrically connected to each other. Conductive patterns 410 and 220 may partially overlap in the z-axis direction to form a plate capacitor structure, and conductive patterns 420 and 210 may partially overlap in the z-axis direction to form a plate capacitor structure. Conductive patterns 210 and 220 in the same conductive structure may form a sidewall capacitor structure, and conductive patterns 410 and 420 in the same conductive structure form a sidewall capacitor structure.

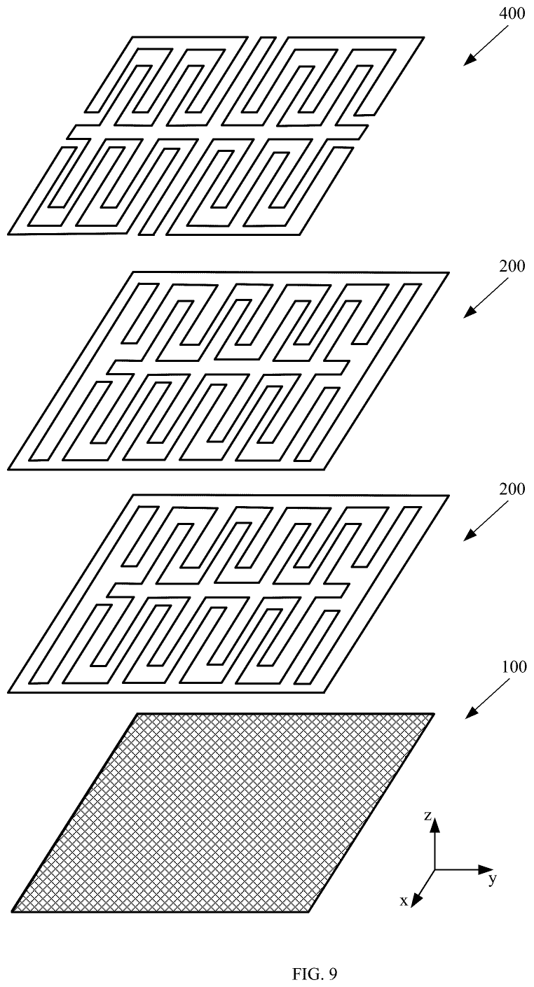

Referring now to FIG. 9, shown is a decomposed structure diagram of a fourth example capacitor, in accordance with embodiments of the present invention. The example capacitor can include bottom conductive structure 100, at least two middle conductive structures 200, and top layer conductive structure 400 sequentially arranged. Conductive patterns 210 of two middle conductive structures 200 and conductive pattern 410 of top conductive structure 400 can connect to the first capacitive pole and are electrically connected to each other. Bottom conductive structure 100, conductive patterns 220 of two first middle conductive structures 200, and conductive pattern 420 of top conductive structure 400 can connect to the second capacitive pole and are electrically connected to each other. Conductive pattern 410 and adjacent conductive pattern 220 may partially overlap in the z-axis direction to form a plate capacitive structure. Conductive pattern 420 and adjacent conductive pattern 210 may partially overlap in the z-axis direction to form a plate capacitor structure. Conductive patterns 210 and 220 in the same conductive structure may form a sidewall capacitor structure, and conductive patterns 410 and 420 in the same conductive structure may form a sidewall capacitor structure. In this example, the capacitor mainly can include a sidewall capacitor.

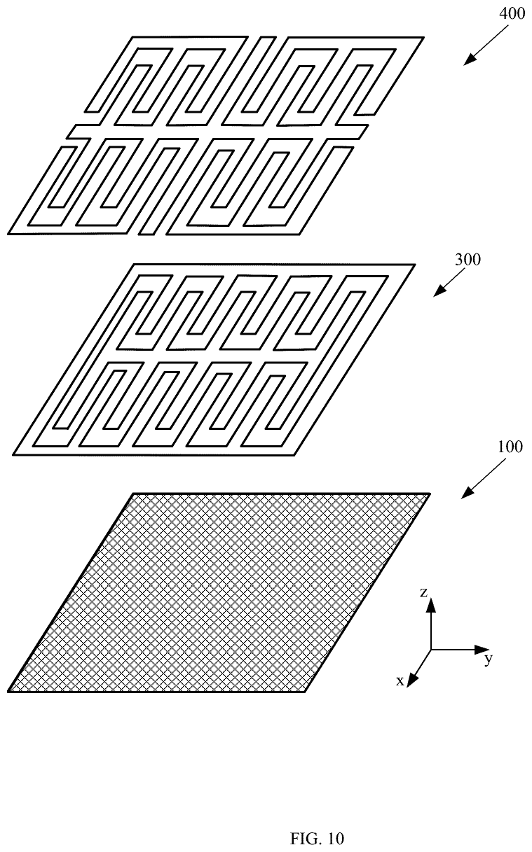

Referring now to FIG. 10, shown is a decomposed structure diagram of a sixth example capacitor, in accordance with embodiments of the present invention. The capacitor can include bottom conductive structure 100, one first middle conductive structure 300, and top layer conductive structure 400 sequentially arranged. Conductive pattern 310 of first middle conductive structure 300 and conductive pattern 410 of top conductive structure 400 can connect to the first capacitive pole and may be electrically connected to each other. Bottom conductive structure 100, conductive pattern 320 of first middle conductive structure 300, and fourth conductive pattern 420 of top conductive structure 400 can connect to the second capacitive pole and are electrically connected to each other. Conductive patterns 410 and 320 may be staggered in the z-axis direction, conductive patterns 420 and 310 may be staggered in the z-axis direction. Conductive patterns 410 and 310 may partially overlap in the z-axis direction, and conductive patterns 420 and 320 may partially overlap in the z-axis direction. However, since conductive patterns 410 and 310 can connect to the same capacitive pole, and conductive patterns 420 and 320 can connect to the same capacitive pole, they may not form a plate capacitor structure. Conductive patterns 310 and 320 in the same conductive structure may form a sidewall capacitor structure, and conductive patterns 410 and 420 in the same conductive structure may form a sidewall capacitor structure. In this example, the capacitor may only include a sidewall capacitor.

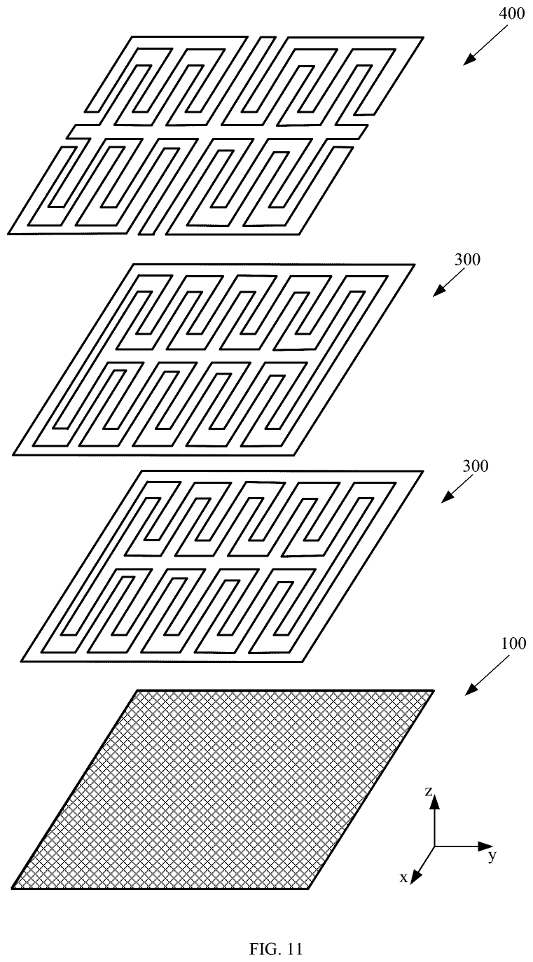

Referring now to FIG. 11, shown is a decomposed structure diagram of a sevenths example capacitor, in accordance with embodiments of the present invention. The capacitor can include bottom layer conductive structure 100, at least two second middle conductive structures 300, and top layer conductive structure 400 sequentially arranged. Conductive pattern 310 of middle conductive structure 300 and conductive pattern 410 of top conductive structure 400 can connect to the first capacitive pole and may be electrically connected to each other. Bottom conductive structure 100, conductive pattern 320 of middle conductive structure 300, and conductive pattern 420 of top conductive structure 400 can connect to the second capacitive pole and can be electrically connected to each other. Conductive patterns 410 and 320 may be staggered in the z-axis direction, and conductive patterns 420 and 310 may be staggered in the z-axis direction. Conductive patterns 410 and 310 may partially overlap in the z-axis direction, and conductive patterns 420 and 320 may partially overlap in the z-axis direction. However, since conductive patterns 410 and 310 can connect to the same capacitive pole, and conductive patterns 420 and 320 can connect to the same capacitive pole, they cannot form a plate capacitor structure. Conductive patterns 310 and 320 in the same conductive structure may form a sidewall capacitor structure, and conductive patterns 410 and 420 in the same conductive structure form a sidewall capacitor structure. In this example, the capacitor only can include a sidewall capacitor.

In some embodiments, each layer in the capacitor can be arranged in an array form. Middle conductive structures 200 and 300 can include multiple conductive patterns 210 and 310 arranged in an array, as well as conductive patterns 220 and 320. Top conductive structure 400 can include multiple conductive patterns 410 and 420 arranged in an array. Bottom conductive structure 100 may refer to multiple bottom conductive structures 100 arranged in an array, or one bottom conductive structure 100 that matches the size of the above array. Multiple conductive patterns 210 and 310, conductive patterns 220 and 320, conductive pattern 410, and conductive pattern 420 can be arranged in one-to-one correspondence. Bottom conductive structure 100 is stacked on the lower side of the above structure, and its projection area along the stacking direction covers the above structure. Middle conductive structure 200, middle conductive structure 300, top conductive structure 400, and bottom conductive structure 100 arranged in the array can connect to each other through their respective connecting parts to form a capacitive array. In this way, the capacitor structure provided in particular embodiments can be elastically arranged into any shaped capacitor array through the connecting parts.

Particular embodiments disclose a capacitor that can include a bottom conductive structure, at least one middle conductive structure, and a top conductive structure sequentially arranged. For example, the middle conductive structure can include a first conductive pattern and a second conductive pattern that form an interdigital pattern, while the top conductive structure can include a third conductive pattern and a fourth conductive pattern that form an interdigital pattern. The first conductive pattern and the third conductive pattern can be electrically connected to each other and can connect to the first capacitive pole, while the bottom conductive structure, second conductive pattern, and fourth conductive pattern may be electrically connected to each other and can connect to the second capacitive pole. Adjacent conductive patterns that do not belong to the same capacitive pole may partially overlap in the stacking direction. Also in particular embodiments, a sidewall capacitor can be formed between two conductive patterns in the same layer of the capacitor, the capacitance density per unit capacitance may be increased, production costs is reduced, the impact of parasitic capacitance on the circuit can be reduced, and the accuracy of the capacitor can accordingly be improved.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A capacitor, comprising:
a) a bottom conductive structure;
b) at least one middle conductive structure, each middle conductive structure having a first conductive pattern and a second conductive pattern surrounding an outer side of the first conductive pattern, wherein the first conductive pattern and the second conductive pattern of each layer of the middle conductive structure form an interdigitated structure;
c) a top conductive structure, comprising a third conductive pattern and a fourth conductive pattern arranged at an outer side of the third conductive pattern, wherein the third conductive pattern and the fourth conductive pattern form an interdigitated structure; and
d) wherein the bottom conductive structure, at least one middle conductive structure, and the top conductive structure are sequentially stacked along a first direction, adjacent conductive structures at least partially overlap in the stacking direction, all of the first conductive patterns and the third conductive patterns are electrically connected to each other as a first capacitive pole, and the bottom conductive structure, all of the second conductive patterns and the fourth conductive pattern are electrically connected to each other as a second capacitive pole.

2. The capacitor of claim 1, wherein the first conductive pattern comprises a first comb tooth pattern, the second conductive pattern comprises a second comb tooth pattern, the third conductive pattern comprises a third comb tooth pattern, the fourth conductive pattern comprises a fourth comb tooth pattern, and the third comb tooth pattern and the fourth comb tooth pattern are interdigitated to each other.

3. The capacitor of claim 2, wherein:
a) the middle conductive structure comprises at least one first middle conductive structure, wherein the first middle conductive structures are stacked when an amount of the first middle conductive structure is greater than one;
b) each of the first middle conductive structures comprises the first conductive pattern and the second conductive pattern surrounding the outer side of the first conductive pattern, and the first conductive pattern and the second conductive pattern of each layer of the middle conductive structure form an the interdigitated structure; and
c) a number of teeth in the first comb tooth pattern of the first conductive pattern is less than a number of teeth in the second comb tooth pattern of the second conductive pattern.

4. The capacitor of claim 2, wherein:
a) the middle conductive structure comprises at least one second middle conductive structure, wherein the second middle conductive structure are stacked when an amount of the second middle conductive structure is greater than one;
b) each of second middle conductive structure comprises the first conductive pattern and the second conductive pattern surrounding the outer side of the first conductive pattern, the first conductive pattern and the second conductive pattern of each layer of the second middle conductive structure form the interdigitated structure; and
c) a number of teeth in the first comb tooth pattern of the first conductive pattern is greater than a number of teeth in the second comb tooth pattern of the second conductive pattern.

5. The capacitor of claim 2, wherein:
a) the middle conductive structure comprises at least one first middle conductive structure and at least one second middle conductive structure;
b) the second middle conductive structure and the first middle conductive structure are alternately stacked between the bottom conductive structure and the top conductive structure;
c) each of the first middle conductive structures comprises the first conductive pattern and the second conductive pattern surrounding the outer side of the first conductive pattern, and the first conductive pattern and the second conductive pattern of each layer of the middle conductive structure form an the interdigitated structure; and
d) each of second middle conductive structure comprises the first conductive pattern and the second conductive pattern surrounding the outer side of the first conductive pattern, and the first conductive pattern and the second conductive pattern of each layer of the second middle conductive structure form the interdigitated structure.

6. The capacitor of claim 5, wherein:
a) the first conductive pattern comprises the first comb tooth pattern, and the second conductive pattern comprises the second comb tooth pattern;
b) the projections of the first comb tooth pattern and the second comb tooth pattern of the adjacent middle conductive structures overlap in the first direction;
c) the third conductive pattern comprises third comb tooth pattern and the fourth conductive pattern comprises fourth comb tooth pattern;
d) the projections of the third comb tooth pattern and the adjacent second comb tooth pattern partially overlap in the first direction; and
e) the projections of the fourth comb tooth pattern and adjacent first comb tooth pattern partially overlap in the first direction, wherein the first direction is the stacking direction of the capacitor.

7. The capacitor of claim 5, wherein:
a) the first middle conductive structure is adjacent to the top conductive structure; and
b) the projections of the first comb tooth pattern of the first middle conductive structure and the fourth comb tooth pattern partially overlap in the first direction, and the projections of the second comb tooth pattern of the first middle conductive structure and the third comb tooth pattern partially overlap in the first direction.

8. The capacitor of claim 1, wherein the third conductive pattern and the fourth conductive pattern form a sidewall capacitor structure, and the first conductive pattern and the second conductive pattern in the same layer form a sidewall capacitor structure.

9. The capacitor of claim 5, wherein the third conductive pattern and adjacent second conductive pattern form a plate capacitor structure, the fourth conductive pattern and adjacent first conductive pattern form a plate capacitor structure, and the first conductive pattern and the second conductive pattern in adjacent two layers form a plate capacitor structure.

10. The capacitor of claim 5, wherein:
a) the third conductive pattern further comprises a first top connecting part arranged along a second direction, the third comb tooth pattern comprises multiple third tooth parts arranged parallel along the third direction, the multiple third tooth parts are connected to the first top connecting part, and the multiple third tooth parts are configured to extend along a direction away from the first top connecting part;
b) the fourth conductive pattern comprises multiple fourth comb tooth patterns, wherein the fourth comb tooth pattern comprises a second top connecting part arranged along the second direction and multiple fourth tooth parts arranged parallel along the third direction, multiple fourth tooth parts are connected to the side edge of the second top connecting part, and multiple fourth tooth parts are configured to extend along the direction from the second top connecting part to the first top connecting part; and
c) the second direction is perpendicular to the first direction, and the third direction is perpendicular to both the first direction and second direction.

11. The capacitor of claim 10, wherein:
a) multiple fourth comb tooth patterns are symmetrically arranged on both sides of the first top connecting part, and the second top connecting part is parallel to the first top connecting part;
b) a first interval is arranged between the adjacent second top connecting part located on the same side of the first top connecting part, and the third tooth parts extend to the first interval in the third direction; and
c) the fourth tooth parts located on both sides of the first top connecting part extend towards the first top connecting part, second intervals are arranged between the opposite fourth tooth parts located on both sides of the first top connecting part, and the first top connecting part passes through each of the second intervals.

12. The capacitor of claim 6, wherein:
a) the first conductive pattern is configured as fishbone shaped, comprising a middle strip-shaped connecting part arranged along the second direction;
b) the first comb tooth pattern comprises multiple first tooth parts arranged in parallel along the third direction;
c) multiple first tooth parts are connected to the middle strip-shaped connecting part, and multiple first tooth parts extend along direction away from the middle strip-shaped connecting part;
d) the second conductive pattern comprises an edge annular connecting part, and the second comb tooth pattern comprises multiple second tooth parts arranged in parallel along the third direction; and
e) multiple second tooth parts are connected to side edges of the edge annular connecting part extending along the second direction, and multiple second tooth parts extend along the direction from the edge annular connecting part to the middle strip-shaped connecting part.

13. The capacitor of claim 12, wherein two ends the middle strip-shaped connecting part of the first middle conductive structure are provided with the first tooth parts, the third tooth parts corresponding to the first tooth parts in the first direction is arranged at near the end position of the first top connecting part, and two ends of the middle strip-shaped connecting part of the second middle conductive structure are not provided with the first tooth parts.

14. The capacitor of claim 12, wherein two ends the middle strip-shaped connecting part of the first middle conductive structure are not provided with the first tooth parts, the third tooth parts corresponding to the first tooth parts in the first direction are not arranged near the end position of the first top connecting part, and two ends of the middle strip-shaped connecting part of the second middle conductive structure are provided with the first tooth parts.

15. The capacitor of claim 1, wherein:
a) the middle conductive structure comprises multiple first conductive patterns and second conductive patterns arranged in an array;
b) the top conductive structure comprises multiple third conductive patterns and fourth conductive patterns arranged in an array; and
c) multiple first conductive patterns, second conductive patterns, third conductive patterns, and fourth conductive patterns arranged in a one-to-one correspondence.

16. The capacitor of claim 1, wherein the bottom conductive structure, at least one middle conductive structure, and the top conductive structure are connected through conductive via.

17. The capacitor of claim 1, wherein the second capacitive pole is led out through the bottom conductive structure, and the first capacitive pole is led out through the third conductive pattern of the top conductive structure.

18. The capacitor of claim 1, wherein the bottom conductive structure is arranged at the second metal layer of the device or at any layer larger than the second metal layer to reduce parasitic capacitance.
